(19) United States
(12) Patent Application Publication
(10) Pub. No.: US 2026/0036904 A1
(43) Pub. Date: Feb. 5, 2026

(54) PHOTOSENSITIVE RESIN COMPOSITION, METHOD FOR PRODUCING CURED RELIEF PATTERN, AND SEMICONDUCTOR DEVICE

(71) Applicant: ASAHI KASEI KABUSHIKI KAISHA, Tokyo (JP)

(72) Inventors: Jingchi GAO, Tokyo (JP); Tomohito OGURA, Tokyo (JP); Shota IWAMA, Tokyo (JP)

(73) Assignee: ASAHI KASEI KABUSHIKI KAISHA, Tokyo (JP)

(21) Appl. No.: 19/123,551

(22) PCT Filed: Oct. 25, 2023
(86) PCT No.: PCT/JP2023/038561

§ 371 Date: Apr. 23, 2025

(30) Foreign Application Priority Data
Oct. 28, 2022 (JP) 2022-173650

(51) Int. Cl. G03F 7/038; C08G 73/12; G03F 7/40; H01L 21/027

(52) U.S. Cl. CPC G03F 7/0387; C08G 73/126; C08G 73/127; G03F 7/40; H01L 21/0273

(57) ABSTRACT

The present invention provides a photosensitive resin composition which contains (A) a polyimide precursor that has a repeating structure represented by formula (1), and (B) a photoradical initiator. (In formula (1), X1 represents a tetravalent organic group; Y1 represents a divalent organic group; m represents an integer of 1 or more; R1 and R2 each represent a hydrogen atom, a radically polymerizable group or an organic group represented by formula (2). In formula (2), R3, R4 and Rz each independently represent a monovalent organic group having 2 to 20 carbon atoms and not containing a fluorine atom, or alternatively, in cases where one of the R3, R4 and Rz moieties is a hydrogen atom, the other moieties are each a monovalent organic group having 2 to 20 carbon atoms and not containing a fluorine atom, and at least one of the other moieties has a branched chain or a cyclic structure.)

### FIELD

The present invention relates to a polyimide precursor, to a photosensitive resin composition comprising the polyimide precursor, to a method for producing a cured relief pattern obtained by curing the photosensitive resin composition, to a cured relief pattern, and to a semiconductor device and display device having the cured relief pattern.

### BACKGROUND

Conventionally, insulating materials for electronic parts and passivation films, surface protecting films or interlayer dielectric films of semiconductor devices have employed polyimide resins which exhibit excellent heat resistance, electrical characteristics and mechanical properties. Among polyimide resins, those provided in the form of photosensitive polyimide precursor compositions can easily form heat-resistant cured relief pattern coating films by thermal imidization treatment involving coating, exposure, development and curing of the compositions. Such photosensitive polyimide precursor compositions allow this process to be drastically shortened compared to conventional non-photosensitive polyimide materials.

As micronization of semiconductors advances, extreme low-κ (ELK) layers having low permittivity are being introduced into semiconductor devices in order to reduce signal delay. Materials with porous structures are being used to lower the permittivity of ELK layers. One of the problems with such materials, however, is their weak mechanical strength. This has resulted in risk of fracture of the ELK layer due to stress on the ELK layer from bumps on the semiconductor surface during the solder reflow step, which requires a high-temperature of 260° C., for example. In consideration of i-line transmittance and low stress of pattern protective films used as protective films for interlayer dielectric films, PTL 1, for example, describes a polyimide precursor having a specific structure with polymerizable groups on the side chains, for formation of a low stress cured film.

At the same time, recent years have brought changes to the methods of mounting printed wiring boards for semiconductor devices, from the viewpoint of increasing integration and function and miniaturizing chip sizes. There has been a trend away from mounting methods using conventional metal pins and lead-tin eutectic solder, and toward structures wherein polyimide coating films directly contact with solder bumps, such as BGA (ball grid array) and CSP (chip-size packages), that allow high-density mounting. When forming such bump structures, the coating film is required to have high heat resistance and mechanical properties.

### CITATION LIST

### Patent Literature

[PTL 1] Japanese Unexamined Patent Publication No. 2014-201696

### SUMMARY

### Technical Problem

However, one problem with photosensitive polyimide resins used in ELK protective layers is weak adhesiveness onto the aluminum used to form semiconductor electrodes, for example. As a result, delamination takes place between the polyimide resin and the substrate, potentially lowering the reliability of the semiconductor device.

In order to improve semiconductor device reliability there is increasing demand for ELK protective layer films with greater thicknesses (such as 9 μm or greater). The polyimide resins used in ELK protective layers comprise a linear structure backbone in order to impart mechanical properties. Absorption is high at the i-line (365 nm) in the exposure wavelength of the polyimide precursor containing the backbone, resulting in insufficient light quantity reaching the film bottom layer during exposure. Consequently the crosslinking efficiency of the polymer is low in the film bottom layer, making it difficult to obtain a pattern of satisfactory shape.

It is an object of the present invention to provide a semiconductor device that can form a pattern having a satisfactory shape as a thick film, and that has excellent protection of the semiconductor chip and excellent adhesiveness between the surface protecting film and the interlayer dielectric film in the redistribution layer, as well as a method for production of the same.

### Solution to Problem

As a result of extensive research in light of the problems described above, the present inventors have found that if a specific chemical structure is partially introduced as side chains in the polyimide precursor, it is possible to form a thick film pattern from a photosensitive resin composition using the polyimide precursor, so that satisfactory adhesiveness with substrates is exhibited, and the present invention has been thereupon completed. Specifically, the present invention provides the following.

<1>

A photosensitive resin composition comprising:
(A) a polyimide precursor having a repeating structure represented by following formula (1):

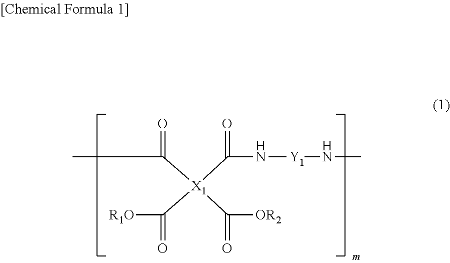

{where:
X₁ is a tetravalent organic group,
Y₁ is a divalent organic group,
m is an integer of 1 or greater, and
R₁ and R₂ are each independently a hydrogen atom, a radical polymerizable group or an organic group represented by following formula (2):

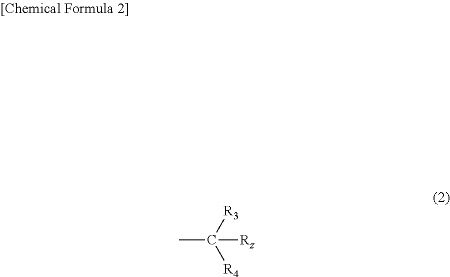

(where R₃, R₄ and R_{z} are each independently a monovalent organic group having 2 to 20 carbon atoms and containing no fluorine, or when any one of R₃, R₄ and R_{z} is a hydrogen atom, the others are monovalent organic groups having 2 to 20 carbon atoms and containing no fluorine atoms, with at least one having a branched-chain or cyclic structure)}, and
(B) a photoradical initiator.
   <2>

The photosensitive resin composition according to [1] above, wherein R₃ is a monovalent organic group having 3 or fewer carbon atoms.

<3>

The photosensitive resin composition according to [1] or [2] above, wherein R₃, R₄ and R_{z} do not contain the radical polymerizable group.

<4>

The photosensitive resin composition according to any one of [1] to [3] above, wherein the radical polymerizable group is a group represented by following formula (3):

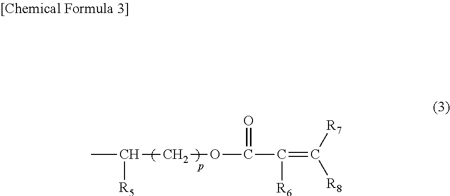

(where R₅ is a hydrogen atom or a monovalent organic group having 1 to 10 carbon atoms, R₆, R₇ and R₈ are each independently a hydrogen atom or a monovalent organic group having 1 to 3 carbon atoms, and p is an integer of 1 to 10).
<5>

The photosensitive resin composition according to [4] above, wherein at least one of R₁ and R₂ in above formula (1) is the group represented by above formula (3), and R₇ and R₈ do not contain the radical polymerizable group.

<6>

The photosensitive resin composition according to [4] or [5] above, wherein the group represented by above formula (3) constitutes 20 to 80 mol % with respect to the total of R₁ and R₂, in above formula (1).

<7>

The photosensitive resin composition according to any one of [1] to [6] above, wherein one of R₃, R₄ and R_{z} is a hydrogen atom.

<8>

The photosensitive resin composition according to any one of [1] to [7] above, wherein Y₁ is represented by following formula (5) or formula (6):

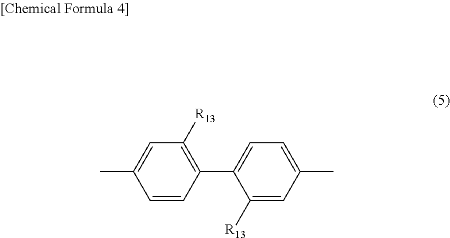

(where each R₁₃ is independently a hydrogen atom, fluorine atom, methyl group or trifluoromethyl group),

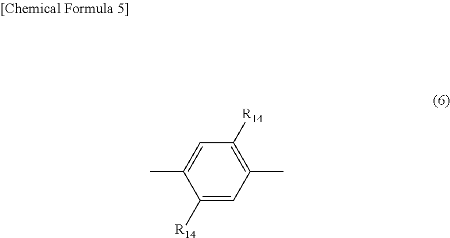

(where each R₁₄ is independently a hydrogen atom or a methyl group).
<9>

The photosensitive resin composition according to any one of [1] to [8] above, wherein X₁ is a group derived from at least one selected from the group consisting of following formulas (7) to (12):

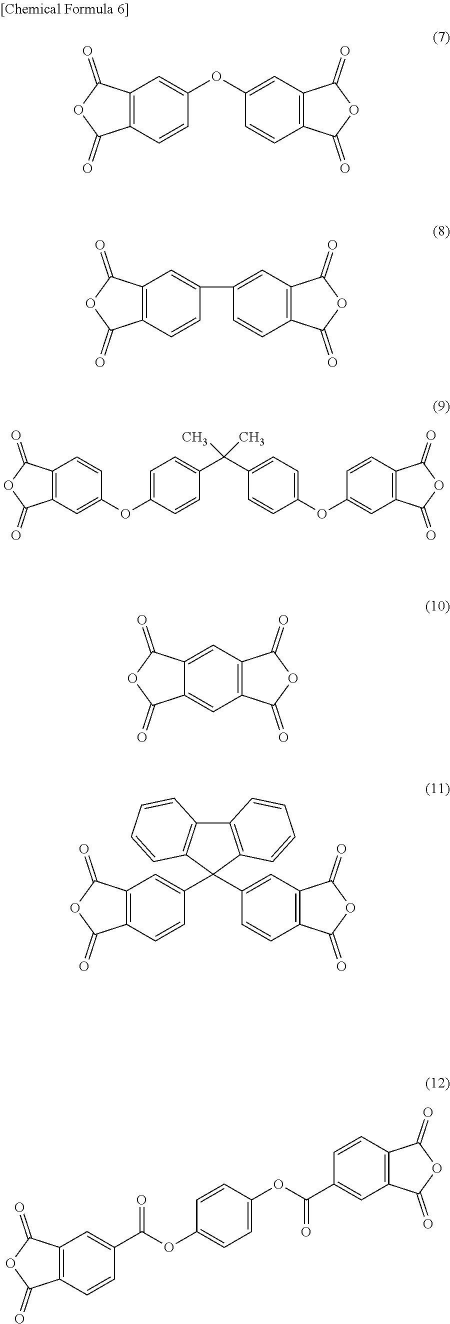 [SMILES: O=C1OC(=O)c2cc(Oc3ccc4c(c3)C(=O)OC4=O)ccc21 ; O=C1OC(=O)c2cc(-c3ccc4c(c3)C(=O)OC4=O)ccc21 ; CC(C)(c1ccc(Oc2ccc3c(c2)C(=O)OC3=O)cc1)c1ccc(Oc2ccc3c(c2)C(=O)OC3=O)cc1 ; O=c1oc(=O)c2cc3c(=O)oc(=O)c3cc12 ; O=C1OC(=O)c2cc(C3(c4ccc5c(c4)C(=O)OC5=O)c4ccccc4-c4ccccc43)ccc21 ; O=C(Oc1ccc(OC(=O)c2ccc3c(c2)C(=O)OC3=O)cc1)c1ccc2c(c1)C(=O)OC2=O]

<10>

The photosensitive resin composition according to [9] above, wherein X₁ is a group derived from at least one selected from the group consisting of above formula (7), (8) and (10) above.

<11>

A photosensitive resin composition comprising:
(A) a polyimide precursor having a repeating structure represented by following formula (1):

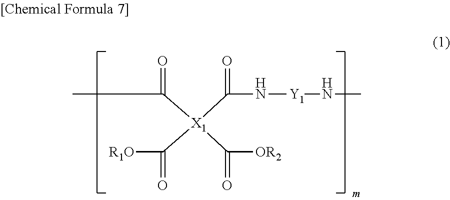

{where
X₁ is a tetravalent organic group,
Y₁ is a divalent organic group,
m is an integer of 1 or greater, and
R₁ and R₂ are each independently a hydrogen atom, a radical polymerizable group or a monovalent organic group having 2 to 20 carbon atoms without a radical polymerizable group}, and
(B) a photoradical initiator,
   wherein after molecular dynamics calculation by Forcite for a structure represented by following formula (13):

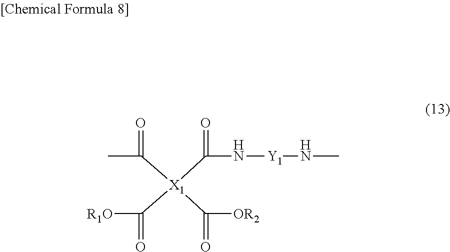

{where X₁, Y₁, R₁ and R₂ are as defined in above formula (1)}
the lowest unoccupied molecular orbital (LUMO) calculated with Dmol3 is −3.00 to −2.59 eV, and the band gap between the highest occupied molecular orbital (HOMO) and LUMO is 1.52 to 2.00 eV.
<12>

The photosensitive resin composition according to any one of [1] to [11] above, wherein a Young's modulus of a cured film obtained by coating a wafer with the photosensitive resin composition and exposing the composition to light and thermosetting the composition at a temperature of 280° C. in a nitrogen atmosphere is 6 GPa or greater.

<13>

A method for producing a cured relief pattern, comprising:
(1) coating a photosensitive resin composition according to any one of [1] to [12] above onto a substrate to form a photosensitive resin layer on the substrate,
(2) exposing the photosensitive resin layer to light,
(3) developing the exposed photosensitive resin layer to form a relief pattern, and
(4) heat treating the relief pattern to form a cured relief pattern.
   <14>

A cured relief pattern comprising a cured product of the photosensitive resin composition according to any one of [1] to [12] above.

<15>

A semiconductor device having the cured relief pattern according to [14] above.

### Advantageous Effects of Invention

According to the invention it is possible to provide a photosensitive resin composition having excellent adhesiveness with metal layers in redistribution layers and that is able to form a satisfactory thick film pattern, as well as a method for producing a cured relief pattern using the photosensitive composition, a cured relief pattern, and a semiconductor device and display device comprising the cured relief pattern.

### DESCRIPTION OF EMBODIMENTS

An embodiment for carrying out the invention (hereunder referred to as “this embodiment”) will now be explained in detail. It is to be understood, incidentally, that the invention is not limited to the embodiment described below and may incorporate various modifications within the scope of the gist thereof.

According to the embodiment, the photosensitive resin composition comprises (A) a polyimide precursor, (B) a photopolymerization initiator, and optionally (C) a crosslinking agent, (D) a solvent and optionally other components. Each of the components will now be described in order.

Throughout the present specification, when multiple structures represented by the same symbol in a general formula are present in a molecule, they may be the same or different.

### Polyimide Precursor Composition

(A) Polyimide Precursor

The polyimide precursor to be used in the photosensitive resin composition may be a polyamic acid ester containing a repeating unit represented by following general formula (1).

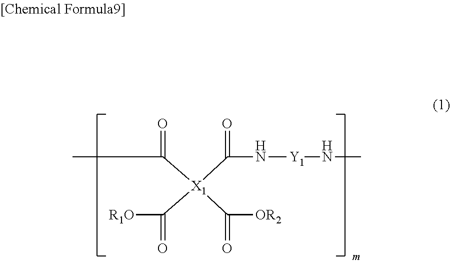

In the formula, X₁ is a tetravalent organic group, Y₁ is a divalent organic group, m is an integer of 1 or greater, and R₁ and R₂ are each independently a hydrogen atom, a radical polymerizable group or an organic group represented by following formula (2):

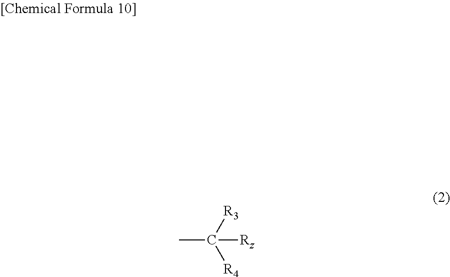

(where R₃, R₄ and R_{z} are each independently a monovalent organic group having 2 to 20 carbon atoms and containing no fluorine, or if any one of R₃, R₄ and R_{z} is a hydrogen atom, the others are monovalent organic groups having 2 to 20 carbon atoms and containing no fluorine atoms, with at least one having a branched-chain or cyclic structure)},
or a monovalent organic group having 2 to 20 carbon atoms without a radical polymerizable group.

For this embodiment, a plurality of different polyamic acid esters represented by general formula (1) may be combined. A polyamic acid ester comprising different polyamic acid esters represented by general formula (1) copolymerized together may also be used.

In general formula (1), the tetravalent organic group represented by X₁ is not particularly restricted but is preferably an organic group having 6 to 40 carbon atoms and more preferably an aromatic group or alicyclic aliphatic group with a —COOR₁ group and —COOR₂ group in mutual ortho positions with a —CONH— group.

Specific examples for X₁ in general formula (1) include groups derived from one or more selected from the group consisting of following formulas (7) to (12).

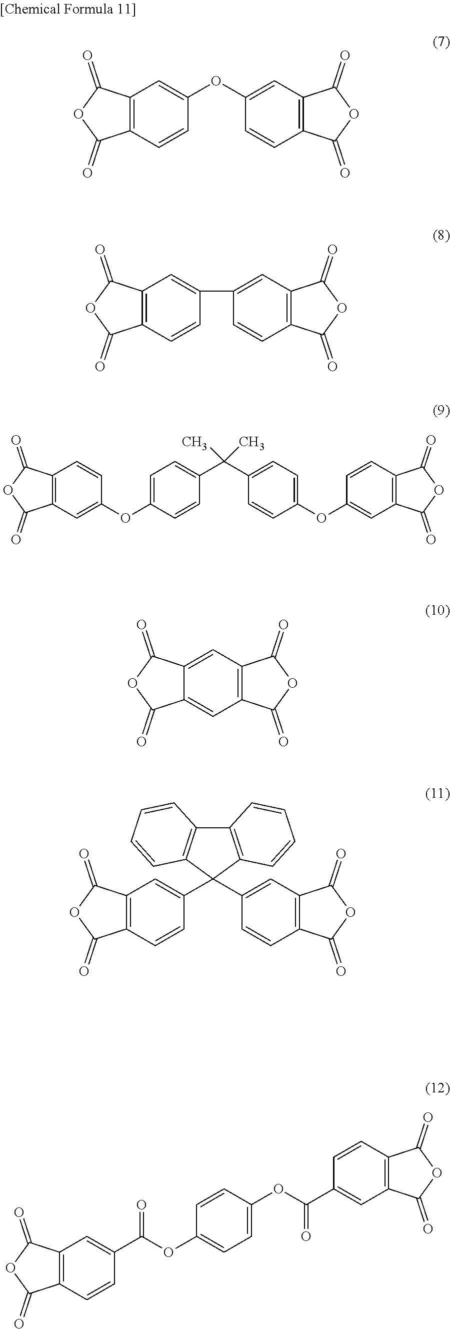

From the viewpoint of the film properties of the cured relief pattern, the tetravalent organic group represented by X₁ in general formula (1) is preferably a group derived from one or more selected from the group consisting of formulas (7), (8) and (10), and more preferably it includes a group derived from either or both pyromellitic dianhydride (PMDA) and biphenyltetracarboxylic dianhydride (BPDA).

R₃, R₄ and R_{z} in general formula (2) are each independently a monovalent organic group having 2 to 20 carbon atoms and containing no fluorine, or when any one of R₃, R₄ and R_{z} is a hydrogen atom, the others are monovalent organic groups having 2 to 20 carbon atoms containing no fluorine atoms, with at least one being a branched-chain or cyclic structure. From the viewpoint of photosensitivity, preferably one of R₃, R₄ or R_{z} is an organic group having 3 or more carbon atoms, and more preferably a monovalent organic group having 3 to 20 carbon atoms containing no fluorine. From the viewpoint of adjustment of the polyimide precursor as described below, preferably one of R₃, R₄ and R_{z} is a hydrogen atom or any one of R₃, R₄ or R_{z} is an organic group having 3 or fewer carbon atoms, and more preferably it is a methyl group. From the viewpoint of adhesiveness, preferably none of R₃, R₄ and R_{z} contain radical polymerizable groups, and more preferably they contain no fluorine.

From the viewpoint of photosensitivity, the radical polymerizable group in general formula (1) is preferably a group represented by following formula (3):

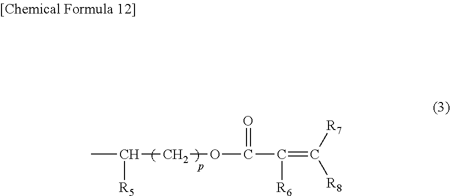

(where R₅ is a hydrogen atom or an organic group having 1 to 10 carbon atoms, R₆, R₇ and R₈ are each independently a hydrogen atom or a monovalent organic group having 1 to 3 carbon atoms, and p is an integer of 1 to 10).

R₅ in general formula (3) is preferably a hydrogen atom or a monovalent organic group having 1 to 10 carbon atoms, and from the viewpoint of photosensitivity of the photosensitive resin composition, it is more preferably a hydrogen atom or a monovalent organic group having 1 to 5 carbon atoms. R₆ in general formula (3) is preferably a hydrogen atom or a monovalent organic group having 1 to 3 carbon atoms, and from the viewpoint of photosensitivity of the photosensitive resin composition, it is more preferably a hydrogen atom or a methyl group. Preferably R₇ and R₈ are each independently a hydrogen atom or a monovalent organic group having 1 to 3 carbon atoms, and from the viewpoint of photosensitivity of the photosensitive resin composition, they are each more preferably a hydrogen atom. The letter p in general formula (3) is preferably an integer of 1 to 10, and from the viewpoint of photosensitivity it is more preferably an integer of 2 to 4.

While the reason for the effect of the invention has not been fully ascertained, the inventors believe it to be the following. Photoabsorption by a polyimide precursor is generally known to be due to charge mobility from diamine sites to acid anhydride sites. Therefore a secondary alcohol or tertiary alcohol is used during introduction of the R₁ and R₂ side chains in formula (1) to introduce high-bulk functional groups, thereby inhibiting the planarity of —X₁—CONH—Y₁ in the polyamic acid main chain and breaking the conjugated system. This presumably inhibits charge mobility from nitrogen atoms to the aromatic ring of the acid anhydride, helping to reduce absorption by polyamic acid.

In order to reduce the absorbance of the polyimide precursor, preferably the energy level of the lowest unoccupied molecular orbital (LUMO) of the polyimide precursor is high, and more preferably the band gap between the LUMO and the highest occupied molecular orbital (HOMO) is also increased. In order for the polyimide precursor represented by formula (1) to have suitable absorbance, preferably after structural optimization of the structure represented by following formula (13):

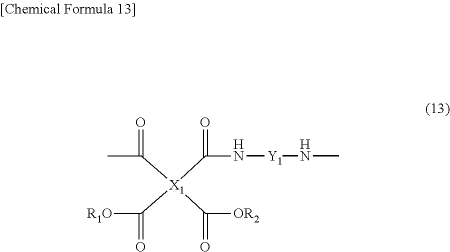

{where the definitions of X₁, Y₁, R₁ and R₂ are the same as in formula (1)}
by molecular dynamics calculation using Forcite, the (LUMO) calculated with Dmol3 is −3.00 to −2.59 eV, also preferably the band gap between the HOMO and LUMO is 1.52 to 2.00 eV, and more preferably the LUMO is −2.85 to −2.59 eV and the band gap between the HOMO and LUMO is 1.57 to 1.90 eV.

The secondary alcohol to be used for the embodiment may be one represented by following formula (4), for example:

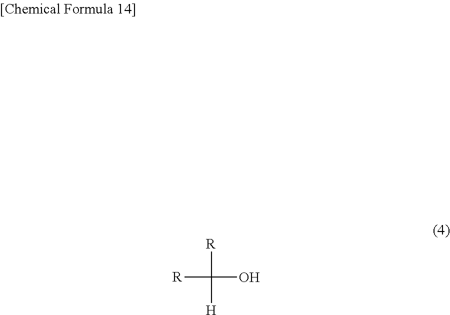

{where each R independently represents the same or a different straight-chain or cyclic hydrocarbon group containing no fluorine atoms, preferably each independently is a monovalent organic group having 2 to 20 carbon atoms and containing no fluorine atoms, and more preferably it is the same or a different straight-chain or branched hydrocarbon group having 2 to 12 carbon atoms and containing no fluorine atoms}.

The tertiary alcohol to be used for the embodiment may be one represented by following formula (14), for example:

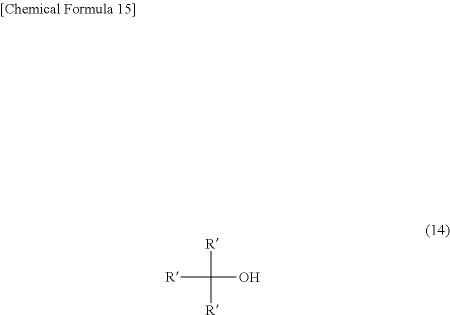

{where each R′ independently represents a monovalent organic group, preferably represents a straight-chain or cyclic hydrocarbon group containing no fluorine atoms, and more preferably, each is independently a straight-chain or branched-chain hydrocarbon group having 2 to 20 carbon atoms containing no fluorine atoms, or a cyclic hydrocarbon group having 3 to 20 carbon atoms and containing no fluorine atoms}.

Regarding the side chains of the polyimide precursor represented by R₁ or R₂, side chains with polymerizable groups represented by formula (3) form polymers by photopolymerization during exposure or by thermal polymerization during curing, thus inhibiting interaction of the polyimide with the substrate and lowering adhesion. It was therefore considered to introduce into the polymer some side chains without polymerizable groups represented by formula (2), in order to reduce formation of adhesion-lowering polymer and thus improve adhesiveness of the photosensitive resin composition. From the same viewpoint, it is also preferred for at least one of R₁ and R₂ in formula (1) to be a group represented by formula (3), and for neither of R₇ and R₈ in formula (3) to contain a radical polymerizable group.

From the viewpoint of photosensitivity and mechanical properties of the photosensitive resin composition, the proportion of the total monovalent organic groups represented by general formula (2) above and monovalent organic groups represented by general formula (3) above with respect to the total of R₁ and R₂ in general formula (1) is preferably 80 mol % or greater. The proportion of monovalent organic groups represented by general formula (3) above with respect to the total of R₁ and R₂ is preferably 20 mol % to 80 mol %. In addition, the proportion of the total of monovalent organic groups represented by general formula (2) above and monovalent organic groups represented by general formula (3) above with respect to the total of R₁ and R₂ in general formula (1) is 90 mol % or greater, and more preferably the total of monovalent organic groups represented by general formula (3) above with respect to the total of R₁ and R₂ is 30 mol % to 70 mol %.

From the viewpoint of the Young's modulus and chemical resistance, Y₁ in general formula (1) is preferably a divalent organic group containing an aromatic group, although this is not particularly limited to Y₁. Specifically, Y₁ is preferably a divalent organic group including at least one structure represented by general formula (5) and general formula (6). The structure of Y₁ may be one single type or a combination of two or more types.

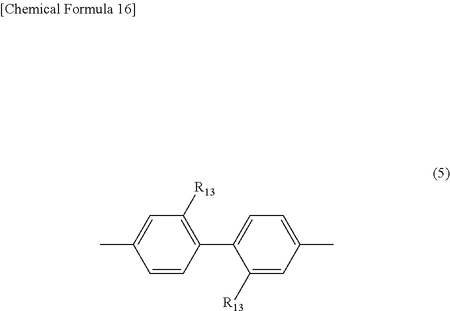

(In the formula, each R₁₃ independently represents a hydrogen atom, a fluorine atom, a methyl group or a trifluoromethyl group.)

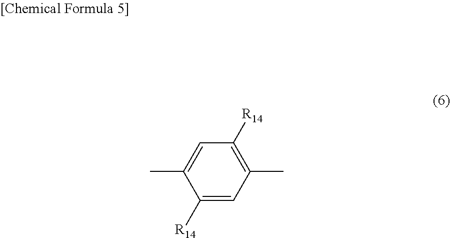

(In the formula, each R₁₄ independently represents a hydrogen atom or a methyl group.)

### Method for Preparing Polyimide Precursor (A)

The polyimide precursor represented by general formula (1) above for this embodiment can be obtained, for example, by reacting a tetracarboxylic dianhydride containing a tetravalent organic group X₁ having 6 to 40 carbon atoms, with hydroxyl groups of (a) a monovalent organic group represented by general formula (2) or general formula (3) above, to prepare a partially esterified tetracarboxylic acid (hereunder also referred to as “acid/ester”), and then polycondensing with a diamine containing a divalent organic group Y₁ represented by general formula (5) or general formula (6).

### Preparation of Acid/Ester

Examples of tetracarboxylic dianhydrides containing a tetravalent organic group X₁ having 6 to 40 carbon atoms for this embodiment include pyromellitic anhydride, diphenyl ether-3,3′,4,4′-tetracarboxylic acid dianhydride, benzophenone-3,3′,4,4′-tetracarboxylic acid dianhydride, biphenyl-3,3′,4,4′-tetracarboxylic acid dianhydride, 9,9-bis(3,4-dicarboxyphenyl)fluorene dianhydride, 1,4-phenylene bis(1,3-dioxo-1,3-dihydroisobenzofuran-5-carboxylate), diphenylsulfone-3,3′,4,4′-tetracarboxylic acid dianhydride, diphenylmethane-3,3′,4,4′-tetracarboxylic acid dianhydride, 2,2-bis(3,4-phthalic anhydride)propane and 2,2-bis(3,4-phthalic anhydride)-1,1,1,3,3,3-hexafluoropropane. Any of these may be used alone, or in combinations of two or more.

Examples of compounds having radical polymerizable groups represented by general formula (3) above for this embodiment include 2-acryloyloxyethyl alcohol, 1-acryloyloxy-3-propyl alcohol, 2-acrylamidoethyl alcohol, methylolvinyl ketone, 2-hydroxyethylvinyl ketone, 2-hydroxy-3-methoxypropyl acrylate, 2-hydroxy-3-butoxypropyl acrylate, 2-hydroxy-3-phenoxypropyl acrylate, 2-hydroxy-3-butoxypropyl acrylate, 2-hydroxy-3-1-butoxypropyl acrylate, 2-hydroxy-3-cyclohexyloxypropyl acrylate, 2-methacryloyloxyethyl alcohol, 1-methacryloyloxy-3-propyl alcohol, 2-methacrylamidoethyl alcohol, 2-hydroxy-3-methoxypropyl methacrylate, 2-hydroxy-3-butoxypropyl methacrylate, 2-hydroxy-3-phenoxypropyl methacrylate, 2-hydroxy-3-butoxypropyl methacrylate, 2-hydroxy-3-1-butoxypropyl methacrylate and 2-hydroxy-3-cyclohexyloxypropyl methacrylate.

Examples of secondary alcohols having groups represented by general formula (2) above, containing no fluorine atoms and also containing no polymerizable groups, include isopropyl alcohol, 2-butanol, 2-pentanol, 1-cyclopropylethanol, 3-pentanol, 2-hexanol, 3-hexanol, 2,4-dimethyl-3-pentanol, 2-heptanol, 3-heptanol, 4-heptanol, 3,3-dimethyl-2-butanol, 2-methyl-3-hexanol, 4-methyl-2-pentanol, 2,5-dimethyl-3-hexanol, 4-methyl-2-pentanol, 2-methylhexanol, 3-methylhexanol, 4-methylhexanol, 3,5-dimethylhexanol, 2-methyl-3-octanol, 2-undecanol, 3-undecanol, 5-undecanol, cyclopentanol, cyclohexanol, cycloheptanol, 1-cyclohexyl-1-butanol, exo-norborneol, 1-phenylethyl alcohol, 1-phenyl-1-propanol, 2-methoxy-2-phenylethanol, 1,3-bis(benzyloxy)-2-propanol, 3-hydroxy tetrahydrofuran and tetrahydro-4-pyranol.

Examples of tertiary alcohols having groups represented by general formula (2) above, containing no fluorine atoms and also containing no polymerizable groups, include t-butyl alcohol, t-amyl alcohol, 1-ethynyl-1-cyclopropanol and 1-adamantanol.

The tetracarboxylic dianhydride and the (a) alcohol may be dissolved and mixed in a reaction solvent in the presence of a basic catalyst such as pyridine to promote half esterification reaction of the acid dianhydride, to obtain the desired acid/ester. The reaction conditions are preferably a reaction temperature of 20 to 50° C., with stirring for 4 to 30 hours.

The reaction solvent is preferably one that dissolves the acid/ester and the polyimide precursor as the polycondensation product of the acid/ester and diamine. The reaction solvent may be, for example, one from among N-methyl-2-pyrrolidone, N,N-dimethylacetamide, N,N-dimethylformamide, dimethyl sulfoxide, tetramethylurea, γ-butyrolactone, ketones, esters, lactones, ethers, halogenated hydrocarbons, hydrocarbons, acetone, methyl ethyl ketone, methyl isobutyl ketone, cyclohexanone, methyl acetate, ethyl acetate, butyl acetate, diethyl oxalate, ethyleneglycol dimethyl ether, diethyleneglycol dimethyl ether, tetrahydrofuran, dichloromethane, 1,2-dichloroethane, 1,4-dichlorobutane, chlorobenzene, o-dichlorobenzene, hexane, heptane, benzene, toluene and xylene. If necessary, these may be used alone, or two or more may be used in admixture.

Examples of diamines containing a divalent organic group Y₁ suitable for use for the embodiment include 2,2′-dimethyl-4,4-diaminobiphenyl, 2,2′-bis(trifluoromethyl)-4,4′-diaminobiphenyl, 3,3′-dimethyl-4,4′-diaminobiphenyl, 3,3′-dimethyl-4,4′-diaminodiphenylmethane, 2,2′-dimethyl-4,4′-diaminodiphenylmethane, 2,2′-dimethoxy-4,4′-diaminobiphenyl, 3,3′-dimethoxy-4,4′-diaminobiphenyl, 2,2′,3,3′-tetramethyl-4,4-diaminobiphenyl, 3,3′-dichloro-4,4′-diaminobiphenyl, p-phenylenediamine and 2,5-dimethyl-1,4-phenylenediamine. These may be used alone, or two or more may be used in admixture. Of these, it is preferred to use 2,2′-dimethyl-4,4′-diaminobiphenyl, 2,2′-dimethoxy-4,4′-diaminobiphenyl or p-phenylenediamine, and it is more preferred to use 2,2′-dimethyl-4,4′-diaminobiphenyl and p-phenylenediamine.

The alcohol used for esterification reaction of the tetracarboxylic di anhydride is an alcohol having an olefinic double bond. Specifically it may be, but is not limited to, 2-hydroxyethyl methacrylate, 2-methacryloyloxyethyl alcohol, glycerin diacrylate or glycerin dimethacrylate. These alcohols may be used alone or as mixtures of two or more.

Examples of organic dehydrating agents include dicyclohexylcarbodiimide (DCC), diethylcarbodiimide, diisopropylcarbodiimide, ethylcyclohexylcarbodiimide, diphenylcarbodiimide, 1-ethyl-3-(3-dimethylaminopropyl)carbodiimide and 1-cyclohexyl-3-(3-dimethylaminopropyl)carbodiimide hydrochloride.

Upon completion of the reaction, the water absorption byproduct of the dehydrating condensation agent which is copresent in the reaction solution is filtered if necessary, and then a poor solvent such as water, an aliphatic lower alcohol or their mixture, is loaded into the obtained polymer component to precipitate the polymer component, after which it is repeatedly redissolved and then reprecipitated to purify the polymer, and finally vacuum dried to isolate the desired polyimide precursor. In order to increase the purity, a solution of the polymer may be passed through a column packed with an anion- and cation-exchange resin that has been swelled with an appropriate organic solvent, to remove the ionic impurities.

### (B) Photopolymerization Initiator

The photopolymerization initiator (B) to be used for this embodiment will now be described. The photopolymerization initiator (B) used may be arbitrarily selected as a compound commonly used as a photopolymerization initiator for UV curing, and it may be a photoradical polymerization initiator, for example. Preferred examples include, but are not limited to, benzophenone derivatives such as benzophenone, methyl o-benzoylbenzoate, 4-benzoyl-4′-methyldiphenyl ketone, dibenzyl ketone and fluorenone; acetophenone derivatives such as 2,2′-diethoxyacetophenone, 2-hydroxy-2-methylpropiophenone and 1-hydroxycyclohexylphenyl ketone; thioxanthone derivatives such as thioxanthone, 2-methylthioxanthone, 2-isopropylthioxanthone and diethylthioxanthone; benzyl derivatives such as benzyl, benzyldimethylketal and benzyl-β-methoxyethylacetal; benzoin derivatives such as benzoin and benzoinmethyl ether; oximes such as 1-phenyl-1,2-butanedione-2-(O-methoxycarbonyl)oxime, 1-phenyl-1,2-propanedione-2-(O-methoxy carbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime and 1-phenyl-3-ethoxypropanetrione-2-(O-benzoyl)oxime; N-arylglycines such as N-phenylglycine; peroxides such as benzoyl perchloride; and aromatic biimidazoles. Any of these may be used alone or in combinations of two or more. Oximes are preferred among these photopolymerization initiators (B), particularly from the viewpoint of photosensitivity.

The content of the photopolymerization initiator (B) is 0.1 parts by weight to 20 parts by weight, but from the viewpoint of photosensitivity it is preferably 1 part by weight to 15 parts by weight, with respect to 100 parts by weight of the polyimide precursor (A). Adding the photopolymerization initiator (B) at 0.1 parts by weight or greater with respect to 100 parts by weight of the polyimide precursor (A) will ensure excellent photosensitivity for the photosensitive resin composition, and addition at 20 parts by weight or lower will ensure excellent thick film curability for the photosensitive resin composition.

### (C) Crosslinking Agent

The crosslinking agent (C) to be used for this embodiment will now be described. For higher relief pattern resolution, a monomer with a photopolymerizable unsaturated bond may optionally be added to the negative-type photosensitive resin composition. Such a monomer is preferably a (meth)acrylate compound that undergoes radical polymerization reaction with a photopolymerization initiator, and typically is diethyleneglycol dimethacrylate or tetraethyleneglycol dimethacrylate, for example, but other examples include, without being limited to, ethylene glycol or polyethylene glycol mono or diacrylate and methacrylate, propylene glycol or polypropylene glycol mono or diacrylate and methacrylate, glycerol mono, di or triacrylate and methacrylate, cyclohexane diacrylate and dimethacrylate, 1,4-butanediol diacrylate and dimethacrylate, 1,6-hexanediol diacrylate and dimethacrylate, neopentyl glycol diacrylate and dimethacrylate, bisphenol A mono or diacrylate and methacrylate, benzene trimethacrylate, isobornyl acrylate and methacrylate, acrylamide and its derivatives, methacrylamide and its derivatives, trimethylolpropane triacrylate and methacrylate, glycerol di or triacrylate and methacrylate, pentaerythritol di, tri or tetraacrylate and methacrylate, and ethylene oxide or propylene oxide addition products of these compounds. Preferred among these are bifunctional or greater (meth)acrylate compounds, with bi- to hexafunctional (meth)acrylate compounds being more preferred.

The content of the crosslinking agent (C), such as a monomer with a photopolymerizable unsaturated bond, is preferably 1 part by weight to 80 parts by weight with respect to 100 parts by weight of the polyimide precursor (A), from the viewpoint of improving the relief pattern resolution.

### (D) Solvent

The photosensitive resin composition of the embodiment may comprise a solvent as component (D), for example. The solvent used is preferably a polar organic solvent from the viewpoint of solubility for the polyimide precursor (A). Specifically, the solvent may be N,N-dimethylformamide, N-methyl-2-pyrrolidone, N-ethyl-2-pyrrolidone, N,N-dimethylacetamide, dimethyl sulfoxide, diethyleneglycol dimethyl ether, cyclopentanone, γ-butyrolactone, α-acetyl-γ-butyrolactone, tetramethylurea, 1,3-dimethyl-2-imidazolinone, N-cyclohexyl-2-pyrrolidone or 2-octanone, either alone or in combinations of two or more.

The solvent may be used in a range of 30 parts by weight to 1500 parts by weight and preferably 100 parts by weight to 1000 parts by weight, for example, with respect to 100 parts by weight of the polyimide precursor (A), depending on the coated film thickness and viscosity desired for the negative-type photosensitive resin composition.

A solvent containing an alcohol is preferred from the viewpoint of improving the storage stability of the negative-type photosensitive resin composition. Alcohols that are suitable for use are typically alcohols having alcoholic hydroxyl groups in the molecule and without olefinic double bonds, specific examples of which include alkyl alcohols such as methyl alcohol, ethyl alcohol, n-propyl alcohol, isopropyl alcohol, n-butyl alcohol, isobutyl alcohol and tert-butyl alcohol; lactic acid esters such as ethyl lactate; propyleneglycol monoalkyl ethers such as propyleneglycol-1-methyl ether, propyleneglycol-2-methyl ether, propyleneglycol-1-ethyl ether, propyleneglycol-2-ethyl ether, propyleneglycol-1-(n-propyl)ether and propyleneglycol-2-(n-propyl)ether; monoalcohols such as ethyleneglycol methyl ether, ethyleneglycol ethyl ether and ethyleneglycol-n-propyl ether; 2-hydroxyisobutyric acid esters; and dialcohols such as ethylene glycol and propylene glycol. Of these, lactic acid esters, propyleneglycol monoalkyl ethers, 2-hydroxyisobutyric acid esters and ethyl alcohol are preferred, and ethyl lactate, propyleneglycol-1-methyl ether, propyleneglycol-1-ethyl ether and propyleneglycol-1-(n-propyl)ether are particularly preferred.

When the solvent comprises an alcohol without an olefinic double bond, the content of the alcohol without an olefinic double bond with respect to the entire solvent is preferably 5% by weight to 50% by weight and more preferably 10% by weight to 30% by weight, based on the weight of the entire solvent. These ranges are preferred because when the content of the alcohol without an olefinic double bond is 5% by weight or greater, the storage stability of the negative-type photosensitive resin composition is satisfactory, and if it is 50% by weight or lower, the solubility of the polyimide precursor (A) is satisfactory.

### Other Components

The negative-type photosensitive resin composition of the embodiment may also comprise components other than components (A) to (D). Examples of other components include resin components other than the polyimide precursor (A), sensitizing agents, monomers with photopolymerizable unsaturated bonds, bonding aids, thermal polymerization initiators, azole compounds, hindered phenol compounds and organic titanium compounds.

The negative-type photosensitive resin composition of the embodiment may also comprise a resin component in addition to the polyimide precursor (A). Examples of resin components that may be added to the negative-type photosensitive resin composition include polyimides, polyoxazoles, polyoxazole precursors, phenol resins, polyamides, epoxy resins, siloxane resins and acrylic resins. The content of such resin components is in the range of preferably 0.01 parts by weight to 20 parts by weight with respect to 100 parts by weight of the polyimide precursor (A).

The negative-type photosensitive resin composition of the embodiment may also have a sensitizing agent optionally added in order to increase the photosensitivity. Examples of sensitizing agents include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylideneindanone, p-dimethylaminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzthiazole, 2-(p-dimethylaminostyryl)naphtho(1,2-d)thiazole and 2-(p-dimethylaminobenzoyl)styrene. Any of these may be used alone or in various combinations (such as 2 to 5 different types, for example).

The content of the sensitizing agent is preferably 0.1 parts by weight to 25 parts by weight with respect to 100 parts by weight of the polyimide precursor (A).

An adhesion aid may also be optionally added to the negative-type photosensitive resin composition in order to increase the adhesiveness of the film formed using the negative-type photosensitive resin composition of the embodiment with the substrate. Examples of adhesion aids include silane coupling agents such as γ-aminopropyldimethoxysilane, N-(β-aminoethyl)-γ-aminopropylmethyldimethoxysilane, γ-glycidoxypropylmethyldimethoxysilane, γ-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N-[3-(triethoxysilyl)propyl]phthalamic acid, benzophenone-3,3′-bis(N-[3-triethoxysilyl]propylamide)-4,4′-dicarboxylic acid, benzene-1,4-bis(N-[3-triethoxysilyl]propylamide)-2,5-dicarboxylic acid, 3-(triethoxysilyl)propylsuccinic anhydride and N-phenylaminopropyltrimethoxysilane; and aluminum-based adhesion aids such as aluminum tris(ethylacetoacetate), aluminum tris(acetylacetonate) and aluminum ethylacetoacetate diisopropylate.

Among these adhesion aids it is preferred to use a silane coupling agent, from the viewpoint of adhesive force. The content of the adhesion aid is preferably in the range of 0.5 parts by weight to 25 parts by weight with respect to 100 parts by weight of the polyimide precursor (A).

For this embodiment, a thermal polymerization initiator may be optionally added in order to improve the viscosity during storage and the photosensitivity stability of the negative-type photosensitive resin composition when in the form of a solution containing a solvent. Examples of thermal polymerization initiators that may be used include hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamine ammonium salt and N-nitroso-N-(1-naphthyl)hydroxylamine ammonium salt.

The content of the thermal polymerization initiator is preferably in the range of 0.005 parts by weight to 12 parts by weight with respect to 100 parts by weight of the polyimide precursor (A).

When a substrate made of copper or copper alloy is used, for example, an azole compound may optionally be added to the negative-type photosensitive resin composition to inhibit discoloration of the substrate. Examples of azole compounds include 1H-triazole, 5-methyl-1H-triazole, 5-ethyl-1H-triazole, 4,5-dimethyl-1H-triazole, 5-phenyl-1H-triazole, 4-1-butyl-5-phenyl-1H-triazole, 5-hydroxyphenyl-1H-triazole, phenyltriazole, p-ethoxyphenyltriazole, 5-phenyl-1-(2-dimethylaminoethyl)triazole, 5-benzyl-1H-triazole, hydroxy phenyltriazole, 1,5-dimethyltriazole, 4,5-diethyl-1H-triazole, 1H-benzotriazole, 2-(5-methyl-2-hydroxyphenyl)benzotriazole, 2-[2-hydroxy-3,5-bis(α,α-dimethylbenzyl)phenyl]-benzotriazole, 2-(3,5-di-t-butyl-2-hydroxyphenyl)benzotriazole, 2-(3-t-butyl-5-methyl-2-hydroxyphenyl)-benzotriazole, 2-(3,5-di-t-amyl-2-hydroxyphenyl)benzotriazole, 2-(2′-hydroxy-5′-t-octylphenyl)benzotriazole, hydroxyphenylbenzotriazole, tolyltriazole, 5-methyl-1H-benzotriazole, 4-methyl-1H-benzotriazole, 4-carboxy-1H-benzotriazole, 5-carboxy-1H-benzotriazole, 1H-tetrazole, 5-methyl-1H-tetrazole, 5-phenyl-1H-tetrazole, 5-amino-1H-tetrazole and 1-methyl-1H-tetrazole. Particularly preferred are tolyltriazole, 5-methyl-1H-benzotriazole and 4-methyl-1H-benzotriazole. These azole compounds may be used alone, or mixtures of two or more of them may be used.

The content of the azole compound is preferably 0.1 parts by weight to 20 parts by weight, and from the viewpoint of photosensitivity it is more preferably 0.5 parts by weight to 5 parts by weight, with respect to 100 parts by weight of the polyimide precursor (A). This range is preferred because if the content of the azole compound is 0.1 parts by weight or greater with respect to 100 parts by weight of the polyimide precursor (A), discoloration of the copper or copper alloy surface will be inhibited when the negative-type photosensitive resin composition has been formed on the copper or copper alloy, and if it is 20 parts by weight or lower the photosensitivity will be excellent.

A hindered phenol compound may optionally be added to the negative-type photosensitive resin composition of the embodiment in order to inhibit discoloration on the copper. Additional examples of hindered phenol compounds include, but are not limited to, 2,6-di-t-butyl-4-methylphenol, 2,5-di-t-butyl-hydroquinone, octadecyl-3-(3,5-di-t-butyl-4-hydroxyphenyl) propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N′hexamethylenebis(3,5-di-t-butyl-4-hydroxy-hydrocinnamamide), 2,2′-methylene-bis(4-methyl-6-t-butylphenol), 2,2′-methylene-bis(4-ethyl-6-t-butylphenol), pentaerythrityl-tetrakis[3-(3,5-di-t-butyl-4-hydroxyphenyl)propionate], tris-(3,5-di-t-butyl-4-hydroxybenzyl)-isocyanurate, 1,3,5-trimethyl-2,4,6-tris(3,5-di-t-butyl-4-hydroxybenzyl)benzene, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione and 1,3,5-tris(4-t-butyl-5-ethyl-3-hydroxy-2-methylbenzyl)-1,3,5-triazine-2,4,6-(1H,3H,5H)-trione, Particularly preferred among these is 1,3,5-tris(4-t-butyl-3-hydroxy-2,6-dimethylbenzyl)-1,3,5-triazine-2,4,6-(1H,3H,5H)-trione.

The content of the hindered phenol compound is preferably 0.1 parts by weight to 20 parts by weight, and from the viewpoint of photosensitivity it is more preferably 0.5 parts by weight to 10 parts by weight, with respect to 100 parts by weight of the polyimide precursor (A). These ranges are preferred because if the content of the hindered phenol compound is 0.1 parts by weight or greater with respect to 100 parts by weight of the polyimide precursor (A), then discoloration and corrosion of the copper or copper alloy will be prevented when the negative-type photosensitive resin composition has been formed on the copper or copper alloy, for example, while if it is 20 parts by weight or lower the photosensitivity will be excellent.

For this embodiment, an organic titanium compound may be used to improve the ductility after humid heat durability testing. Organic titanium compounds that may be used are not particularly restricted so long as they have an organic chemical substance bonded to a titanium atom via a covalent bond or ionic bond.

Specific examples of organic titanium compounds include following I) to VII):
I) titanium chelate compounds: among which are preferred titanium chelates having two or more alkoxy groups for storage stability of the negative-type photosensitive resin composition, and for obtaining a satisfactory pattern, with specific examples including titanium bis(triethanolamine)diisopropoxide, titanium di(n-butoxide)bis(2,4-pentanedionate), titanium diisopropoxide bis(2,4-pentanedionate), titanium diisopropoxide bis(tetramethylheptanedionate) and titanium diisopropoxide bis(ethylacetoacetate).
II) Tetraalkoxytitanium compounds: Examples are titanium tetra(n-butoxide), titanium tetraethoxide, titanium tetra(2-ethylhexoxide), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide and titanium tetrakis [bis{2,2-(allyloxymethyl)butoxide}].
III) Titanocene compounds: Examples are pentamethylcyclopentadienyltitanium trimethoxide, bis(η⁵-2,4-cyclopentadien-1-yl)bis(2,6-difluorophenyl)titanium and bis(η⁵-2,4-cyclopentadien-1-yl)bis(2,6-difluoro-3-(1H-pyrrol-1-yl)phenyl)titanium.
IV) Monoalkoxytitanium compounds: Examples are titanium tris(dioctylphosphate)isopropoxide and titanium tris(dodecylbenzenesulfonate)isopropoxide.
V) Titanium oxide compounds: Examples are titanium oxide bis(pentanedionate), titanium oxide bis(tetramethylheptanedionate) and phthalocyaninetitanium oxide.
VI) Titanium tetraacetylacetonate compounds: An example is titanium tetraacetylacetonate.
VII) Titanate coupling agents: An example is isopropyltridodecylbenzenesulfonyl titanate.

Among these compounds I) to VII), the organic titanium compound is preferably one or more compounds selected from the group consisting of I) titanium chelate compounds, II) tetraalkoxytitanium compounds and III) titanocene compounds, from the viewpoint of exhibiting more satisfactory chemical resistance. Particularly preferred are titanium diisopropoxide bis(ethylacetoacetate), titanium tetra(n-butoxide) and bis(nη⁵-2,4-cyclopentadien-1-yl)bis(2,6-difluoro-3-(1H-pyrrol-1-yl)phenyl)titanium.

These organic titanium compounds are added at preferably 0.01 to 10 parts by weight and more preferably 0.1 to 2 parts by weight with respect to 100 parts by weight of the polyimide precursor used as component (A). An amount of organic titanium compound addition of 0.01 parts by weight or greater will help in exhibiting adhesiveness, and an amount of 10 parts by weight or lower will help in providing satisfactory storage stability.

The total amount of components of the total solid content in the photosensitive resin composition of the photosensitive resin composition of the embodiment, minus the polyimide precursor (A), is preferably 26% by weight or greater and lower than 60% by weight, with respect to the polyimide precursor (A). If the total component amount minus the polyimide precursor (A) is 26% by weight or greater, it will be possible to shorten the absolute initial developing time after the film coating step and the baking process, thus increasing the throughput for the semiconductor manufacturing process. If the total component amount minus the polyimide precursor (A) is lower than 60% by weight, it will be possible to maintain the film properties after humid heat durability testing.

From the viewpoint of protecting the ELK layer of a semiconductor element, the photosensitive resin composition of the embodiment preferably has a Young's modulus of 6 GPa or greater for the cured film obtained by curing and exposure of the wafer and thermosetting at a temperature of 280° C. in a nitrogen atmosphere.

This embodiment can provide a cured relief pattern comprising the cured photosensitive resin composition as explained above, and it also exhibits excellent adhesiveness with the metal layer in the redistribution layer as well as excellent thick film formability.

### Method for Producing Cured Relief Pattern

According to the embodiment it is possible to provide a method for producing a cured relief pattern comprising following steps (1) to (4):
(1) a step of coating a substrate with a photosensitive resin composition of the embodiment as described above to form a photosensitive resin layer on the substrate,
(2) a step of exposing the photosensitive resin layer,
(3) a step of developing the exposed photosensitive resin layer to form a relief pattern, and
(4) a step of heat treating the relief pattern to form a cured relief pattern.

Each of the steps will now be explained.

(1) Step of Coating Negative-Type Photosensitive Resin Composition onto a Substrate to Form Photosensitive Resin Layer on the Substrate

In this step, a photosensitive resin composition of the embodiment is coated onto a substrate and then dried if necessary, to form a photosensitive resin layer. A negative-type and positive-type photosensitive resin composition may be used in the method for producing a cured relief pattern, with the negative-type photosensitive resin composition preferably being coated onto the substrate. The coating method may be a method conventionally used for coating of photosensitive resin compositions, and for example, a method of coating with a spin coater, bar coater, blade coater, curtain coater, screen printer or the like, or a method of spray coating with a spray coater, may be used.

If necessary, the coating film composed of the photosensitive resin composition may be dried, using a drying method such as air-drying, heat drying with an oven or hot plate, or vacuum drying. Drying of the coating film is preferably carried out under conditions in which imidization of the polyimide precursor (A) does not take place in the negative-type photosensitive resin composition. For air-drying or heat drying specifically, the drying may be carried out under conditions of 20° C. to 140° C. for 1 minute to 1 hour. Heating is preferably carried out at 100° C. to 120° C. for 230 seconds to 250 seconds, and more preferably heating is carried out at 110° C. for 240 seconds. Carrying out step (1) in this manner can form a photosensitive resin layer on the substrate.

### (2) Photosensitive Resin Layer Light Exposure Step

In this step, the photosensitive resin layer that has been formed in step (1) is exposed to an ultraviolet light source using an exposure device with a contact aligner, mirror projector and stepper, either directly or through a patterned photomask or reticle.

Next, if necessary, it may be subjected to post-exposure baking (PEB) and/or pre-development baking with a prescribed combination of temperature and time, for the purpose of improving the photosensitivity. The range of baking conditions is preferably a temperature of 40° C. to 120° C. and a time of 10 seconds to 240 seconds, but there is no limitation to this range so long as the properties of the negative-type photosensitive resin composition are not inhibited.

### (3) Step of Developing Exposed Photosensitive Resin Layer to Form Relief Pattern

In this step, the unexposed sections of the exposed photosensitive resin layer are developed and removed. The developing method for development of the photosensitive resin layer after exposure (irradiation) may be a conventionally known photoresist developing method, selected from among any methods such as a rotating spray method, paddle method or dipping method with ultrasonic treatment. Following development, post-development baking may be carried out with the desired combination of temperature and time necessary for the purpose of adjusting the relief pattern shape.

The developing solution used for development is preferably a good solvent for the negative-type photosensitive resin composition, or a combination of a good solvent and a poor solvent, for example. Preferred examples of good solvents include N-methyl-2-pyrrolidone, N-cyclohexyl-2-pyrrolidone, N,N-dimethylacetamide, cyclopentanone, cyclohexanone, γ-butyrolactone and α-acetyl-γ-butyrolactone. Preferred examples of poor solvents include toluene, xylene, methanol, ethanol, isopropyl alcohol, ethyl lactate, propyleneglycol methyl ether acetate and water. When a good solvent and a poor solvent are used in admixture, the proportion of the poor solvent with respect to the good solvent is preferably adjusted by the solubility of the polymer in the negative-type photosensitive resin composition. The solvents may be used in combinations of two or more, including several solvents.

### (4) Step of Heat Treating Relief Pattern to Form Cured Relief Pattern

In this step, the relief pattern obtained by development is heated to disperse the photosensitive component, while imidizing the polyimide precursor (A) to convert it to a cured relief pattern comprising a polyimide. The heat curing method may be selected from among various methods including those using a hot plate, using an oven, or using a temperature program-settable heating oven, for example. The heating may be carried out under conditions of 200° C. to 400° C. for 30 minutes to 5 hours, for example. The atmosphere gas for heat curing may be air, or an inert gas such as nitrogen or argon. From the viewpoint of controlling the Young's modulus of the cured film, thermosetting is preferably carried out in a nitrogen atmosphere at a temperature of preferably 200° C. to 400° C., more preferably 250° C. to 300° C. and even more preferably 270° C. to 290° C.

### Semiconductor Device

The embodiment further provides a semiconductor device having a cured relief pattern obtained by the method for producing a cured relief pattern described above. For example, it can provide a semiconductor device having a substrate as the semiconductor element, and a cured relief pattern of a polyimide formed on the substrate by the method for producing a cured relief pattern described above.

The invention can also be applied in a method for producing a semiconductor device, with some of the steps consisting of the aforementioned method for producing a cured relief pattern, using a semiconductor element as the substrate. The semiconductor device of the invention can be produced by forming a cured relief pattern by the method for producing a cured relief pattern described above, as a surface protecting film, interlayer dielectric film, rewiring insulating film, flip-chip device protective film or a protective film for a semiconductor device having a bump structure, and combining that with a known method for producing a semiconductor device.

### Display Device

The embodiment also provides a display device comprising a display element and a cured film formed on top of the display element, wherein the cured film is the cured relief pattern described above. The cured relief pattern may be layered in direct contact with the display element, or it may be layered across another layer. Examples of cured films include surface protecting films for TFT liquid crystal display units and color filter elements, insulating films, and flattening films, as well as protrusions for MVA liquid crystal display devices, and partitions for organic EL element cathodes.

In addition to application in semiconductor devices as described above, the photosensitive resin composition of the invention is also useful for use in interlayer dielectric films for multilayer circuits, cover coats for flexible copper-clad sheets, solder resist films and liquid crystal oriented films.

### EXAMPLES

Examples of the invention will now be described to illustrate the effect of the invention, with the understanding that the invention is not to be limited in any way by the Examples. The following materials and measuring methods were used in the Examples.

### Measurement and Evaluation Methods

(1) Measurement of i-Line Absorbance

The i-line absorbance of the polyimide precursor was measured by preparing an NMP solution containing 0.1% by weight (wt %) of the polyimide precursor, packing it into a 1 cm quartz cell, and then using an UV-1800 analyzer by Shimadzu Corp. for measurement at medium scan speed and a sampling pitch of 0.5 nm. The i-line absorbance of the polyimide precursor as the polymer sample was evaluated on the following scale:
A: absorbance of <1.0;
B: absorbance of ≥1.0 and ≤1.2;
C: absorbance of >1.2.

### (2) Evaluation of Pattern Formation (Lithography)

Each of the resin compositions prepared in the formulation examples was spin coated onto a 6-inch silicon wafer substrate to a cured film thickness of 9 μm, and pre-baked for 4 minutes at 110° C. The obtained coating film was exposed by i-line irradiation at an exposure dose of 450 mJ/cm² through a test patterned reticle using an NSR200518A stepper (product of Nikon Corp.) having an i-line (365 nm) exposure wavelength. Next, rotating spray development was carried out with a D-SPIN developing machine (product of Sokudo Co.) using cyclopentanone as the developing solution at 23° C., for 1.4 times the time required for the unexposed sections to be completely dissolved and disappear, after which rotating spray rinsing was carried out for 10 seconds with propyleneglycol monomethylether acetate to form a relief pattern composed of a resin film. This was followed by curing at 280° C. for 2 hours in a VF200B vertical curing furnace with a nitrogen atmosphere (Koyo Thermo System Co., Ltd.), to obtain a cured relief pattern.

The pattern shape of each obtained pattern was observed using a scanning electron microscope (S-4800 by Hitachi High-Technologies Corp.). For resolution, a pattern having openings of different areas was formed by exposure through a test patterned reticle, by the same method described above, and the length on the opening side of the mask corresponding to the taper angle with the minimum area, among those with no residue on the bottom of the obtained pattern and with proper taper angles on the side walls, was recorded as the minimum opening. The photosensitive resin compositions prepared in the formulation examples were evaluated on the following scale:
A: minimum opening of <8 μm;
B: minimum opening of ≥8 μm and ≤10 μm;
C: minimum opening of >10 μm.

### (3) Adhesion Evaluation (Peel Test)

Each of the resin compositions prepared in the formulation examples was spin coated onto a 6-inch silicon wafer substrate having an aluminum (Al) vapor deposition layer on the surface, to a cured film thickness of 9 μm, and pre-baked for 4 minutes at 110° C. A vertical curing furnace (Model VF-2000B by Koyo Lindbergh) was then used for heat curing treatment for 2 hours at 280° C., to produce a wafer with a polyimide resin film formed over it.

The measured peel strength may be the peel strength between a glass substrate and a polyimide film measured by the 180 degrees (°) peel method of JISK6854-1 using a sample comprising the polyimide film formed on the glass substrate. The peel strength was measured under the following conditions.
Apparatus: RTG-1210 (A&D Co., Ltd.)
Measuring temperature: room temperature
Peel rate: 50 mm/min
Atmosphere: air
Sample width: 5 mm.

The Al adhesion of the photosensitive resin composition was evaluated on the following scale:
A: peel strength of >0.3 N/mm;
B: peel strength of ≥0.2 and ≤0.3 N/mm;
C: peel strength of <0.2 N/mm.

### Production Example 1> (Polymer A: Synthesis of Polyimide Precursor)

### (Reaction Solution I)

After placing 19.63 g (0.09 mol) of pyromellitic anhydride (PMDA) as acid anhydride 1 and 19.13 g (0.19 mol) of 3,3-dimethyl-2-butanol as side chain 1 in a 200 mL volume three-necked flask, 53 g of γ-butyrolactone and 14.24 g (0.18 mol) of pyridine were added and the mixture was stirred at room temperature for 24 hours to obtain reaction solution I.

### (Reaction Solution II)

After placing 18.61 g (0.06 mol) of 4,4′-oxydiphthalic dianhydride (ODPA) as acid anhydride 2 and 16.24 g (0.12 mol) of 2-hydroxyethyl methacrylate (HEMA) as side chain 2 in a 1 liter volume separable flask, 44.35 g of y-butyrolactone and 9.49 g (0.12 mol) of pyridine were added and the mixture was stirred at room temperature for 16 hours to obtain reaction solution II.

Next, reaction solution I and reaction solution II were mixed and cooled to 0° C. or below, and a solution of 60.98 g (0.15 mol) of dicyclohexylcarbodiimide (DCC) dissolved in 60.00 g of γ-butyrolactone was added to the reaction mixture over a period of 20 minutes while stirring.

The reaction temperature was then kept at 2° C. or below while a solution of 27.86 g (0.13 mol) of 2,2′-dimethylbiphenyl-4,4′-diamine (m-TB) as a diamine in 80.00 g of γ-butyrolactone was added dropwise over a period of 30 minutes.

The reaction solution was warmed to room temperature and stirred for 4 hours at room temperature, after which 13.66 g of ethanol was added as an end-capping agent, the mixture was stirred for 30 minutes, and the precipitate formed in the reaction mixture was filtered out to obtain the reaction solution.

A 3 L portion of ethanol was then added to the obtained reaction solution to produce a precipitate of the crude polymer. The produced crude polymer was filtered and dissolved in 600 g of γ-butyrolactone to obtain a crude polymer solution. The obtained crude polymer solution was added dropwise into 6 L of water to precipitate a polymer, and after filtering the precipitate, it was vacuum dried at 40° C. for 72 hours to obtain a powdered polymer (polyimide precursor (polymer A)). The i-line absorbance of the polymer was 0.92, and the evaluation was “A”. The structure represented by general formula (13) for the obtained polymer, was analyzed by structural optimization using the simulation software “Forcite” under the conditions listed in Table 1:

TABLE 1

| | |
|---|---|
| Task | Geometry opt |
| Force field | pcff |
| Quality | medium |

while the lowest unoccupied molecular orbital (LUMO) and the band gap between the highest occupied molecular orbital (HOMO) and LUMO were calculated using the calculation program “Dmol3”, under the conditions listed in Table 2:

TABLE 2

| | |
|---|---|
| Task | Energy |
| Quality | Customized |
| Functional | GGA/PBE |
| Core treatment | All electron |
| Basis set | DNP/4.4 |
| Property | Optics |
| Calculate | 400 lowest singlet state |
| Use | ALDA TD-DFT |

### Production Examples 2 to 10> (Polymers B to J: Synthesis of Polyimide Precursor)

Polymer B to J were synthesized by the same method as the Synthesis Example of Production Example 1, replacing the acid anhydrides, side chains and diamines of reaction solution I and reaction solution II in Production Example 1 with the combinations shown in Table 3, and the i-line absorbances of the polymers were evaluated.

### Production Example 11> (Polymer K: Synthesis of Polyimide Precursor)

After placing 18.61 g (0.06 mol) of 4,4′-oxydiphthalic dianhydride (ODPA) and 19.63 g (0.09 mol) of pyromellitic anhydride (PMDA) as acid anhydrides and 40.61 g (0.15 mol) of 2-hydroxyethyl methacrylate (HEMA) as a side chain in a 1 liter volume separable flask, 102.58 g of γ-butyrolactone and 23.73 g (0.30 mol) of pyridine were added and the mixture was stirred at room temperature for 16 hours.

Next, the reaction solution was cooled to 0° C. or below, and a solution of 60.98 g (0.15 mol) of dicyclohexylcarbodiimide (DCC) dissolved in 60.00 g of γ-butyrolactone was added over a period of 20 minutes while stirring.

The reaction temperature was kept at 2° C. or below while a solution of 27.29 g (0.13 mol) of 2,2′-dimethylbiphenyl-4,4′-diamine (m-TB) as a diamine in 80.00 g of γ-butyrolactone was added dropwise over a period of 30 minutes.

The reaction solution was warmed to room temperature and stirred for 4 hours at room temperature, after which 13.66 g of ethanol was added as an end-capping agent, the mixture was stirred for 30 minutes, and the precipitate formed in the reaction mixture was filtered out to obtain the reaction solution.

A 3 L portion of ethanol was then added to the obtained reaction solution to produce a precipitate of the crude polymer. The produced crude polymer was filtered and dissolved in 600 g of γ-butyrolactone to obtain a crude polymer solution. The obtained crude polymer solution was added dropwise into 6 L of water to precipitate a polymer, and after filtering the precipitate, it was vacuum dried at 40° C. for 72 hours to obtain a powdered polymer (polyimide precursor (polymer K)). When the i-line absorbance of the polymer was measured, the evaluation was “C”.

### Production Example 12> (Polymer M: Synthesis of Polyimide Precursor)

Polymer M was synthesized by the same method as the Synthesis Example of Production Example 11, replacing the acid anhydride and diamine in Production Example 11 with the combination shown in Table 3, and the i-line absorbance of the polymer was evaluated.

TABLE 3

| | | Acid anhydride | Side | | Band | Acid anhydride | Side | | i-line |
|---|---|---|---|---|---|---|---|---|---|
| | Polymer | 1 mol % | chain 1 | LUMO/eV | gap | 2 mol % | chain 2 | Diamine | absorbance |
| Production | A | PMDA 60% | 3,3-Dimethyl-2-butanol | −2.73 | 1.57 | ODPA 40% | HEMA | m-TB | A |
| Example 1 | | | | | | | | | |
| Production | B | PMDA 60% | 4-Methyl-2-pentanol | −2.74 | 1.52 | ODPA 40% | HEMA | m-TB | A |
| Example 2 | | | | | | | | | |
| Production | C | PMDA 60% | 2,5-Dimethyl-3-hexanol | −2.66 | 1.77 | ODPA 40% | HEMA | m-TB | A |
| Example 3 | | | | | | | | | |
| Production | D | PMDA 60% | 1,3-bis(Benzyloxy)-2-propanol | −3.02 | 1.25 | ODPA 40% | HEMA | m-TB | A |
| Example 4 | | | | | | | | | |
| Production | E | PMDA 50% | tert-Amyl alcohol | −2.59 | 1.69 | ODPA 50% | HEMA | m-TB | A |
| Example 5 | | | | | | | | | |
| Production | F | PMDA 60% | 2-Hydroxybutyl methacrylate | −2.85 | 1.51 | ODPA 40% | HEMA | m-TB | B |
| Example 6 | | | | | | | | | |
| Production | G | PMDA 40% | 4-Methyl-2-pentanol | −2.74 | 1.52 | BPDA 60% | HEMA | m-TB | A |
| Example 7 | | | | | | | | | |
| Production | H | PMDA 50% | tert-Amyl alcohol | −2.59 | 1.69 | ODPA 50% | HEMA | m-TB | A |
| Example 8 | | | | | | | | | |
| Production | I | PMDA 60% | Methanol | −3.18 | 1.40 | ODPA 40% | HEMA | m-TB | C |
| Example 9 | | | | | | | | | |
| Production | J | PMDA 60% | 4-(Trifluoromethyl)cyclohexanol | −3.11 | 1.24 | ODPA 40% | HEMA | m-TB | B |
| Example 10 | | | | | | | | | |
| Production | K | PMDA 60% | HEMA | −2.89 | 1.51 | ODPA 40% | HEMA | m-TB | C |
| Example 11 | | | | | | | | | |
| Production | M | PMDA 40% | HEMA | −2.89 | 1.51 | BPDA 60% | HEMA | m-TB | C |
| Example 12 | | | | | | | | | |

### Examples 1 to 8 and Comparative Examples 1 to 4

After dissolving 10.00 g of polymers A to M obtained in the Production Examples, 0.50 g of 1-phenyl-2-[(benzoyloxy)imino]-1-propanone as a photopolymerization initiator, 1.40 g of tetraethyleneglycol dimethacrylate as a crosslinking agent, and 1.20 g of N-phenyldiethanolamine and 0.05 g of ethyl 7-(diethylamino) coumarin-3-carboxylate as sensitizing agents, in 18.49 g of γ-butyrolactone, a microfilter with a pore size of 1 μm was used for filtration to prepare a photosensitive resin composition. Table 4 shows the polymers used in the Examples and Comparative Examples, and the evaluation results for pattern formability and adhesion of the photosensitive resin compositions.

TABLE 4

| | Polymer | Pattern formation | Al adhesion |
|---|---|---|---|
| Example 1 | A | A | A |
| Example 2 | B | A | A |
| Example 3 | C | A | A |
| Example 4 | D | B | B |
| Example 5 | E | A | B |
| Example 6 | F | A | B |
| Example 7 | G | A | A |
| Example 8 | H | A | A |
| Comp. Example 1 | I | C | A |
| Comp. Example 2 | J | C | C |
| Comp. Example 3 | K | B | B |
| Comp. Example 4 | M | C | C |

As demonstrated by the Examples, the i-line absorbance was reduced by introduction of side chains with a branched structure into the polymer. Photosensitive resin compositions using the polymers exhibited satisfactory pattern formability as thick films. Adhesiveness to aluminum was also found to be significantly improved with the photosensitive resin compositions using polymers with introduction of non-crosslinked side chains.

### INDUSTRIAL APPLICABILITY

Using a photosensitive resin composition of the invention makes it possible to form an insulating layer that exhibits excellent adhesiveness with substrates after coated film curing, and allows opening of stable via patterns, so that it can be suitably used in the field of photosensitive materials with utility in the manufacture of electrical and electronic materials, such as semiconductor devices and multilayer circuit boards.

1. A photosensitive resin composition comprising:
(A) a polyimide precursor having a repeating structure represented by following formula (1): 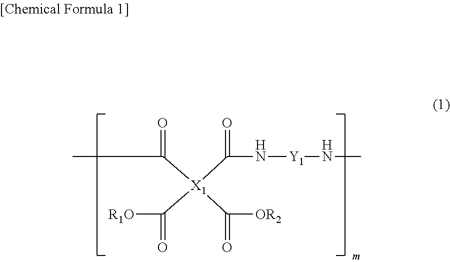
{where:
X₁ is a tetravalent organic group,
Y₁ is a divalent organic group,
m is an integer of 1 or greater, and
R₁ and R₂ are each independently a hydrogen atom, a radical polymerizable group or an organic group represented by following formula (2): 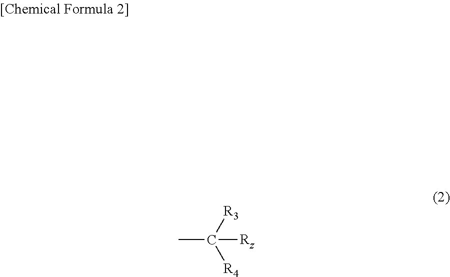
(where R₃, R₄ and R₂ are each independently a monovalent organic group having 1 to 20 carbon atoms and containing no fluorine, or when any one of R₃, R₄ and R_{z} is a hydrogen atom, the others are monovalent organic groups having 1 to 20 carbon atoms and containing no fluorine atoms, with at least one having a branched chain or cyclic structure)}, and
(B) a photoradical initiator.

2. The photosensitive resin composition according to claim 1, wherein R₃ is a monovalent organic group having 3 or fewer carbon atoms.

3. The photosensitive resin composition according to claim 1, wherein R₃, R₄ and R_{z} do not contain the radical polymerizable group.

4. The photosensitive resin composition according to claim 1, wherein the radical polymerizable group is a group represented by following formula (3): 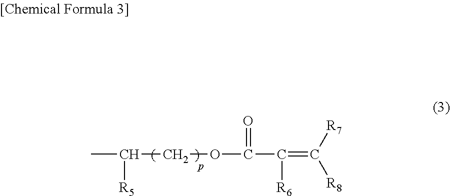
(where R₅ is a hydrogen atom or a monovalent organic group having 1 to 10 carbon atoms, R₆, R₇ and R₈ are each independently a hydrogen atom or a monovalent organic group having 1 to 3 carbon atoms, and p is an integer of 1 to 10).

5. The photosensitive resin composition according to claim 4, wherein at least one of R₁ and R₂ in above formula (1) is the group represented by above formula (3), and R₇ and R₈ do not contain the radical polymerizable group.

6. The photosensitive resin composition according to claim 4, wherein the group represented by above formula (3) constitutes 20 to 80 mol % with respect to the total of R₁ and R₂, in above formula (1).

7. The photosensitive resin composition according to claim 1, wherein one of R₃, R₄ and R_{z} is a hydrogen atom.

8. The photosensitive resin composition according to claim 1, wherein Y₁ is represented by following formula (5) or formula (6): 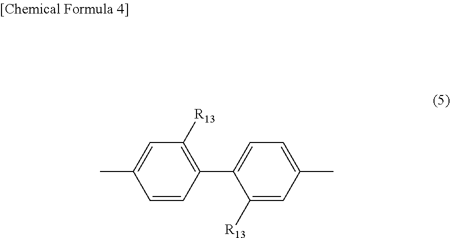
(where each R₁₃ is independently a hydrogen atom, fluorine atom, methyl group or trifluoromethyl group), 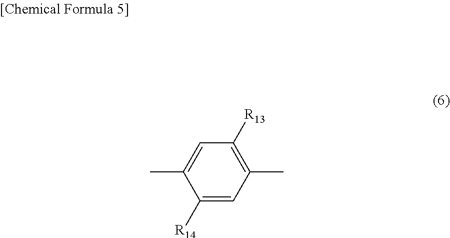
(where each R₁₄ is independently a hydrogen atom or a methyl group).

9. The photosensitive resin composition according to claim 1, wherein X₁ is a group derived from at least one selected from the group consisting of following formulas (7) to (12):

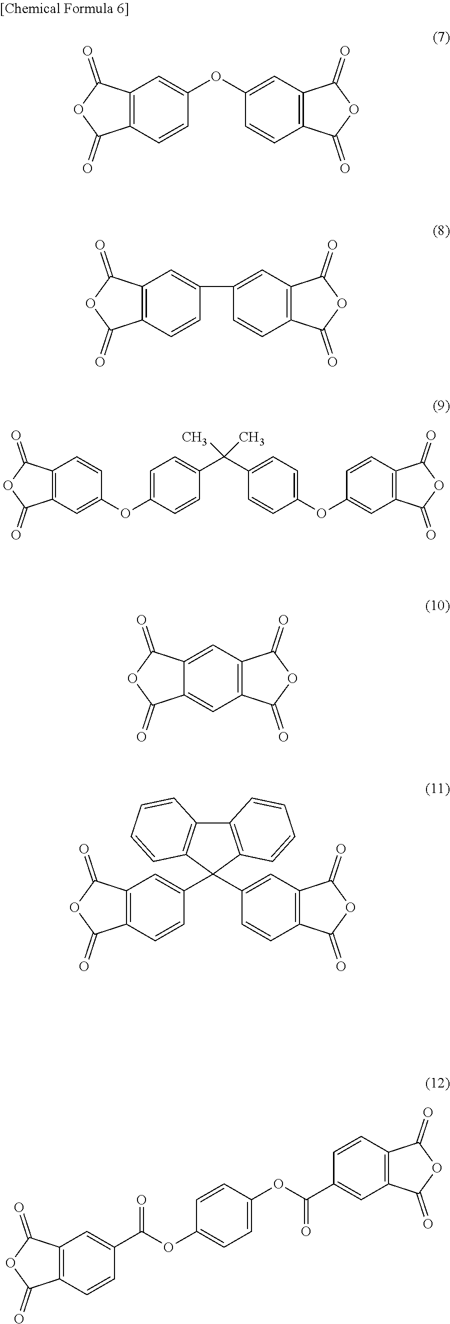 [SMILES: O=C1OC(=O)c2cc(Oc3ccc4c(c3)C(=O)OC4=O)ccc21 ; O=C1OC(=O)c2cc(-c3ccc4c(c3)C(=O)OC4=O)ccc21 ; CC(C)(c1ccc(Oc2ccc3c(c2)C(=O)OC3=O)cc1)c1ccc(Oc2ccc3c(c2)C(=O)OC3=O)cc1 ; O=c1oc(=O)c2cc3c(=O)oc(=O)c3cc12 ; O=C1OC(=O)c2cc(C3(c4ccc5c(c4)C(=O)OC5=O)c4ccccc4-c4ccccc43)ccc21 ; O=C(Oc1ccc(OC(=O)c2ccc3c(c2)C(=O)OC3=O)cc1)c1ccc2c(c1)C(=O)OC2=O]

10. The photosensitive resin composition according to claim 9, wherein X₁ is a group derived from at least one selected from the group consisting of above formulas (7), (8) and (10) above.

11. A photosensitive resin composition comprising:
(A) a polyimide precursor having a repeating structure represented by following formula (1): 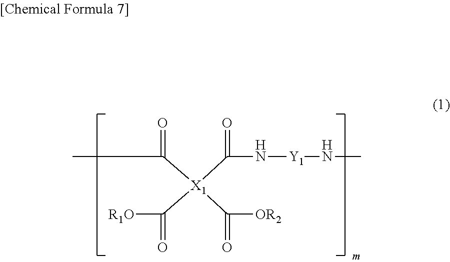
{where
X₁ is a tetravalent organic group,
Y₁ is a divalent organic group,
m is an integer of 1 or greater, and
R₁ and R₂ are each independently a hydrogen atom, a radical polymerizable group or a monovalent organic group having 2 to 20 carbon atoms without a radical polymerizable group}, and
(B) a photoradical initiator,
wherein after molecular dynamics calculation by Forcite for a structure represented by following formula (13): 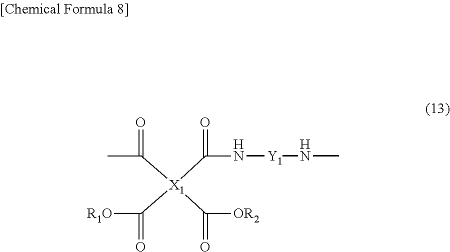
{where X₁, Y₁, R₁ and R₂ are as defined in above formula (1)}
the lowest unoccupied molecular orbital (LUMO) calculated with Dmol3 is −3.00 to −2.59 eV, and the band gap between the highest occupied molecular orbital (HOMO) and LUMO is 1.52 to 2.00 eV.

12. The photosensitive resin composition according to claim 1, wherein a Young's modulus of a cured film obtained by coating a wafer with the photosensitive resin composition and exposing the composition to light and thermosetting the composition at a temperature of 280° C. in a nitrogen atmosphere is 6 GPa or greater.

13. A method for producing a cured relief pattern, comprising:
(1) coating a photosensitive resin composition according to claim 1 onto a substrate to form a photosensitive resin layer on the substrate,
(2) exposing the photosensitive resin layer to light,
(3) developing the exposed photosensitive resin layer to form a relief pattern, and
(4) heat treating the relief pattern to form a cured relief pattern.

14. A cured relief pattern comprising a cured product of the photosensitive resin composition according to claim 1.

15. A semiconductor device having the cured relief pattern according to claim 14.
